(19) United States
(12) Patent Application Publication
(10) Pub. No.: US 2004/0244856 A1
(43) Pub. Date: Dec. 9, 2004

(54) Concatenation module for the control of an electrical valve drive of a fluid power valve arrangement

(75) Inventors: Stephan Schauz, Geislingen/Stg. (DE); Walter Suchy, Stuttgart (DE); Rolf Rohwer, Ostfildern (DE)

Correspondence Address: HOFFMANN & BARON, LLP, 6900 JERICHO TURNPIKE, SYOSSET, NY, 11791, US

(73) Assignee: Festo AG & Co.

(21) Appl. No.: 10/838,978

(22) Filed: May 5, 2004

(30) Foreign Application Priority Data
Jun. 7, 2003 (EP) 03012971.2

(51) Int. Cl. F16K 1/00; F17D 1/00; G11C 8/00; E03B 1/00; E03C 1/00

(52) U.S. Cl. 137/884

(57) ABSTRACT

A concatenation module adapted to be concatenated with further concatenation modules as a battery, comprising a housing and lateral concatenation contacts on the housing for making electrical contact with at least one further concatenation module. The housing is in the form of a three-dimensional circuit substrate and it contains at least one electronic component, arranged on the circuit substrate, for a control function and/or a monitoring function and/or a communication function. When the concatenation modules are assembled as a battery the concatenation contact preferably make flatwise contact with each other.

### BACKGROUND OF THE INVENTION

The invention relates to a concatenation module adapted to be concatenated with further concatenation modules as a battery, comprising a housing and lateral concatenation contacts on the housing for making electrical contact with at least one further concatenation module.

### The Prior Art

Such a concatenation module is for example disclosed in the German patent publication 198 01 234 C2 in the form of a pneumatic valve subassembly. Other clustered arrangements, for example memory programmable controls or the like may comprise such concatenation modules. The valve subassemblies disclosed in the said German patent publication 198 01 234 C2 have a disk-like geometry and may be arranged adjacent to each other. At the top on the pneumatic valve arrangements of the valve subassemblies valve drives are seated and on the concatenation contacts there are decoding chips for the control of the valve drives and for decoding bus signals, which are received by way of the concatenation contacts. The concatenation contacts are designed in the form of resilient contact lugs, of rigid contact lugs or of spring loaded contact pins, which are respectively arranged on the top of the valve subassembly as separate components.

The well known sandwich design is liable to suffer from environmental effects. The saddled decoder chips and the concatenation contacts are exposed so that damage to the decoder chips and oxidation and fouling of the concatenation contacts is likely so that the operational reliability of the valve battery is considerably impaired.

### SHORT SUMMARY OF THE INVENTION

Accordingly one object of the present invention is to provide a concatenation module of the initially described type which has an improved operational reliability.

In order to achieve this and/or other objects appearing from the present specification, claims and drawings, in the present invention a concatenation module is so designed that the housing is in the form of a three-dimensional circuit substrate and it contains at least one electronic component, arranged on the circuit substrate, for a control function and/or a monitoring function and/or a communication function.

For achieving the aim of the invention recourse is furthermore had to a module unit, more particularly a valve subassembly and a battery, more especially a valve battery, comprise at least one concatenation module of the type in accordance with the invention.

The concatenation module integrates essential functions. The housing designed a three-dimensional circuit substrate is of compact design and increases operational safety since it constitutes a substrate element for one or more electrical components. The component(s) are preferably arranged in a protected manner in the interior of the concatenation module. The electrical component can for example be an integrated semiconductor control component, as for example an application specific integrated circuit (ASIC), a printed circuit board, or an interface component for a communication bus or the like. The component may for example be a control component, which controls and/or monitors, for example, a valve drive.

Further advantageous developments of the invention are defined in the claims.

Preferably in the case of the battery-mounted state of the concatenation modules the concatenation contacts lie flatwise against each other. Accordingly the interchangeability of the concatenation module in the module battery is improved. In principle the concatenation contacts could at least partly be designed in the form of plug contacts.

The concatenation contacts are preferably constituted by the housing. The concatenation contacts may also be an integral part of the housing. These measures mean that the electrical operating reliability is improved.

Preferably, as well, the concatenation module has vapor-deposited and/or electroplated and/or hot embossed metallic printed wiring. The printed wiring of the concatenation module may also be constituted by an integrated metallic stamped and bent part which is at least partly surrounded by an injection molding for example. The housing of the concatenation module is for example manufactured using so-called molded interconnect device (MID) technology, that is to say as an injection molded three-dimensional circuit substrate. The substrate simultaneously serves as a housing and as a printed wiring substrate. In the circuit substrate one or more stamped and bent parts may have material cast around them. It is possible as well for an integral stamped and bent part to firstly have material cast around it and then for the connecting sprues between the individual sections of the stamped and bent part to be removed so that electrical insulation of the sections is ensured.

The electrical concatenation contacts are preferably covered over from the outside when the valve battery is mounted. Accordingly spurious contacts, produced for example by short circuiting or the like, are effectively prevented. The functional reliability of the valve battery is improved.

Preferably the concatenation contacts are arranged on opposite sides of the concatenation module. The concatenation modules may be thus placed in a row in an optimum manner. Respectively one pair of concatenation contacts arranged on opposite sides of the concatenation module are preferably associated with one bus conductor. These concatenation contacts are best placed in a row in the mounted state for two or more concatenation modules in accordance with the invention accordingly constitute one electrical data bus.

The concatenation contacts connected with one another by continuous printed wiring. In order to reduce electrical transition resistance the continuous printed wiring preferably constitutes contact faces of the concatenation contacts. This measure serves to provide optimum signal transmission quality.

The at least one component, as for instance a control component and/or a communication component, is best arranged on one or more of the printed wiring elements connecting two or more concatenation contacts arranged on opposite sides of the concatenation module and is electrically connected with this printed wiring element.

It is an advantage for the concatenation module to have a receiving space, which in the mounted state is closed, for one or more electrical components, for example one or more electrical printed circuit boards, ASCICs or the like. The receiving space may for example be shut off, for example, by the module unit mounted on the concatenation module, that is to say by its housing or by some other cover means. Preferably the receiving space is filled with a potting composition. It is preferred for the receiving space to have a substrate structure in it for one of the electrical components. The substrate structure is located for instance on a side wall of the concatenation module housing, which has a group of concatenation contacts. For the production of electrical connections with the electrical component printed wiring elements run from the concatenation contacts to the substrate structure. The signal paths from the concatenation contacts to the electrical component are short.

Concatenation contacts arranged on each side of the concatenation module are best grouped at a contact region. In the case of such contact region it is best for it to be sealed off from the outside by a sealing means, effective toward the outside, as for example a surrounding rubber or plastic seal so that for example splashed water is kept out. The sealing means are preferably integrated in the housing of the concatenation module. The sealing means may be constituted by the housing, which for example has an elastic zone or the like. Consequently the concatenation contacts are protected against environmental effects.

The concatenation contacts may have different preferred designs:

They may be in the form of metallized plastic members, which for example are manufactured using MID technology. However, the preferred design involves metal spring contacts, which for example are constituted by a metallic stamped and bent part. A further preferred design uses so-called fuzz button contacts. Fuzz button contacts, also named contain a resilient metal structure like a ball of thin wire, which in the contact making state resiliently engages a cooperating concatenation contact of an adjacent concatenation module. The metal structure comprises for example beryllium copper wire, which is externally coated with gold. A further possible design involves using concatenation contacts which are constituted at least partially by non-resilient electrical engagement faces.

For the electrical connection of the concatenation contacts of adjacent concatenation modules it is possible as well to have mutually electrically insulated conductors, f. i. arranged in an electrical insulator and made for example of fine gold wire. In the mounted condition the electrical insulator is between adjacent concatenation modules and the electrical conductors connect the concatenation contacts connecting the processing modules, while however being electrically insulated from one another.

The concatenation contacts preferably comprise plastic members. The plastic members are for example biased by a metallic spring arrangement which is more especially provided with an electrically non-conductive coating, by at least one spring. Instead of one or more springs it is possible also to use a metallic spring comb. More particularly in the case of the latter design the electrical non-conductive coating is preferred for electrical insulation of the concatenation contacts from each other. The plastic members are for example in the form of resilient lugs sprayed on the housing of the concatenation module. The spring arrangement or, respectively, the spring comb, is for example a stamped and bent part, which is arranged between the resilient lugs and a housing of the concatenation module and biases the resilient lugs away from the concatenation module. Accordingly even following fatigue of the material of the metallized plastic members there will be an optimum reliability of contact making.

It will be clear that there is an unrestricted variety of combinations of the above mentioned designs of the concatenation contacts in the case of a concatenation module in accordance with the invention.

Preferentially the concatenation module possesses illuminating means for indicating at least one function of the concatenation module, for example “normal operation” or “failure”. The illuminating means, in the case of which it is a question for example of LED's, are preferably arranged in a protected manner in the interior of the concatenation module, light guides, for example of transparent plastic, conducting the light signals, produced by the illuminating means, to the outer face of the concatenation module. The illuminating means are consequently protected from damage or from dirt.

The further preferred design in accordance with the invention is such that the concatenation contacts are essentially constituted by a substrate structure produced by a dual component injection molding method and in the interior of the concatenation module a printed wiring structure is formed on laser-activated material. Although both manufacturing processes are already a known part of MID technology, the invention links the two methods of manufacture, which in the case of a concatenation module for a fluid power means of the above mentioned type represents an independent invention and there is an optimum combination of mechanically loaded concatenation contacts and a fine structure of the layout within the concatenation module. For example the basic housing of the concatenation module consists of metallizable material, which has laser activtable material injected around it. The laser-activatable material serves primarily for insulation. Printed wiring runs from the metallizable material into the interior of the concatenation module to a face of the laser-activatable material, on which printed wiring is produced using a laser.

The following features relate to a modular design, which represents a sub-combination, and thus an independent invention in its own right.

The concatenation module is preferably able to be connected with a module unit to be controlled and/or monitored, the concatenation module and the module unit together forming a battery or cluster which is able to be coupled with further battery modules to constitute a battery. In the case of the module unit it is a question for example of a fluid power, for example pneumatic valve arrangement and/or a valve drive for such a valve arrangement and/or a servicing unit and/or a diagnostics unit. The at least one electrical component serves for control and/or monitoring of the module unit and/or for monitoring the module unit and/or for communication with the module unit and/or the concatenation module with further battery modules or a control and monitoring means for the battery.

In the case of the fluid power module unit the battery module may also be termed a fluid power battery module or as valve subassembly, which is able to be coupled with one or more further such valve subassemblies to provide a valve battery. The concatenation module preferably comprises at least one electrical valve drive for the actuation of the fluid power valve arrangement. It is possible as well for the concatenation module to have connection means for electrical connection and control of an electrical valve drive. The valve drive, which for example comprises one or more electrodynamic or electrostatic actuators, is preferably in the form of a separate module, which is able to be coupled with the concatenation module. The valve drive may also be integrated in the valve arrangement. The concatenation module preferably has means for a power down mode for the valve drive and/or diagnostics means for the valve drive and/or the valve arrangement.

The valve arrangements preferably constitute, in the condition mounted on the valve battery, a continuous fluid supply duct. It is possible as well for the valve arrangement to be able to be coupled with a fluid supply module. The fluid supply module is provided for supply of the valve arrangements with fluid. The fluid supply module may constitute a substrate element, on which the valve subassemblies or, respectively, the fluid power battery modules may be arranged.

Preferably the concatenation module is permanently connected with the module unit, more particularly by bonding or welding. It will be clear that other methods of mounting are possible, f. i. by using screws or the like. In accordance with a further design of the invention the concatenation module is detachably connected with the module unit. If there is a defect in the module unit or the concatenation module one of the components may be readily replaced.

For the electrical connection with the module unit it is an advantage to provide connection means, for example plug connection means. The connection means may advantageously connected in the mounted state with cooperating connecting means of the module unit using a conductive adhesive. The conductive adhesive fills up, for instance, an intermediate space otherwise present between the respective connecting means. During assembly of the concatenation module the connecting means are still comparatively loosely, that is to say with play, plugged together or arranged in some other manner adjacent to each other. The intermediate space between the connecting means is filled with the still liquid conductive adhesive, which after curing provides reliable contact making between the connecting means. All in all a stress-free connection may be produced between the concatenation module and the valve drive.

Further advantageous developments and convenient forms of the invention will be understood from the following detailed descriptive disclosure of several embodiments thereof in conjunction with the accompanying drawings.

### LIST OF THE SEVERAL VIEWS OF THE FIGURES

FIG. 1 shows a first embodiment with a concatenation module in accordance with the invention provided with a valve subassembly.

FIG. 2 shows a valve battery having several lined up valve subassemblies as in the present working example of the invention FIG. 1.

FIG. 3 shows a detailed view of the concatenation module in accordance with FIG. 1 looking obliquely upward, the end face turned toward the concatenation module being visible.

FIG. 4 also shows the concatenation module in accordance with FIG. 1 looking obliquely upward, non-resilient contact faces being visible.

FIG. 5 shows a further design of the concatenation module in accordance with the preceding figures looking obliquely upward with a printed circuit board resting on a substrate structure of the concatenation module.

FIG. 6 shows the concatenation module in accordance with the preceding figures looking obliquely upward with a partially sectioned valve drive mounted thereon.

FIG. 7 shows the concatenation module and the valve drive in a partially sectioned view, the concatenation module being depicted generally along a line A-A in FIG. 1.

FIG. 8 shows a second embodiment of a concatenation module having metal spring contacts.

FIG. 9 shows a stamped and bent part, which serves to form the metal spring contacts of the concatenation module in accordance with FIG. 8.

FIG. 10 shows a side view of the concatenation module in accordance with FIG. 8, lettering on the concatenation contacts being visible.

FIG. 11 is a view of the concatenation module in accordance with FIG. 8, in the case of which a printed circuit board (see FIG. 5) and further electrical components are omitted in order to make the drawing more straightforward so that a substrate structure with electrical contact pads for the printed circuit board is visible.

FIG. 12 shows a third embodiment of a concatenation module in accordance with the invention having fuzz button contacts.

FIG. 13 is a partly sectioned view showing of the concatenation module in according to FIG. 12 along a line B-B, in the case of which the structure of a fuzz button contact is represented diagrammatically.

FIG. 14 a diagrammatic front view of conductors arranged in an elastic insulator for an alternative electrical connection of non-resilient concatenation contacts of a concatenation module, similar to the concatenation modules of FIGS. 11 and 12.

### DETAILED ACCOUNT OF WORKING EMBODIMENTS OF THE INVENTION.

In order to make the drawing more straightforward some individual components of the concatenation module of the invention are omitted, for example printed wiring, integrated circuits and the like.

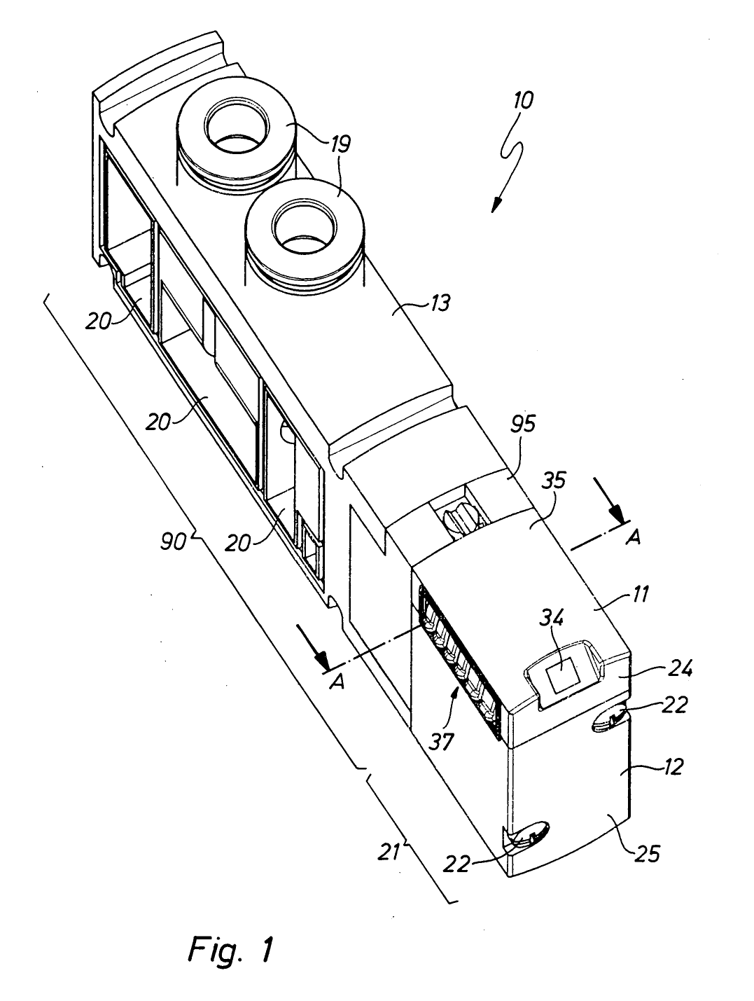

The valve subassembly 10 illustrated in FIG. 1 is a battery module in accordance with the invention, which is designed in accordance with a modular principle. The valve subassembly 10 comprises a structural unit 21 with a concatenation module 11, which in the present case is permanently coupled with a electrical valve drive 12 and comprises a module unit 90, which contains a fluid power valve arrangement 13 and furthermore a pilot control valve unit 95. The structural unit 21 and with it the concatenation module 11, is detachably connected with the module unit 90. The concatenation module 10 controls the valve drive 12. The valve drive 12 could however be detachably connected with the concatenation module 10. The valve drive 12 could also constitute an integral component of the concatenation module 10. In this case the entire structural unit 21 could be termed a concatenation module.

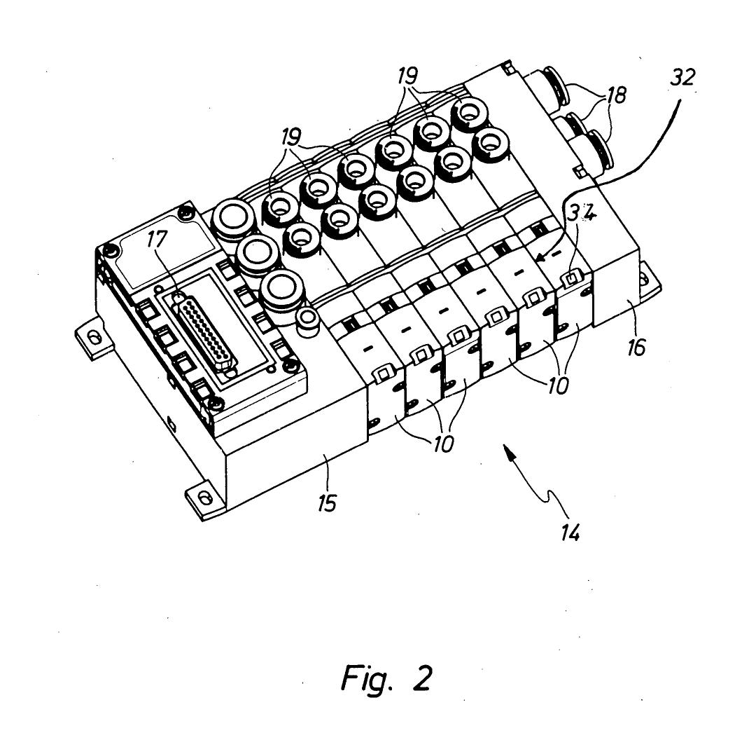

A plurality of valve subassemblies 10 could be joined together as modules as a valve battery 14, that is to say a module battery (FIG. 2). To the side terminating modules 15 and 16 constitute the ends of the valve battery 14. In the terminating module 15 a local control unit (not visible) is arranged for example, which by way of an electrical multiple contact 17 is able to be controlled and monitored and/or configured. Connections or terminals 18 are provided on the terminating module 16 for the supply of the valve subassemblies 10 with a fluid, in the present case compressed air. The local control unit controls and/or monitors the valve subassemblies 10 via a bus 32.

By way of duct sections 20 of the lined up valve arrangements 13 continuous fluid supply ducts are formed, which by way of the connections 18 are able to be supplied with fluid. From same fluid may flow through power connections 19, which are arranged to the front on the valve arrangement 13, in a manner dependent on a valve member, not illustrated, of the valve arrangement 13, which may be actuated by the valve drive 12 directly. The valve drive 12 may be a directly controlling valve drive 4, that is to say, it electrically actuates the valve member of the valve arrangement 13. The valve drive 12 may also contain fluid power pilot valves, which may be electrically actuated. In the present case pilot valves are employed in the pilot valve unit 95, which are actuated by the valve drive 12. In principle any type of electrical actuation is possible in the case of the valve drive 12, as for example electrodynamic and/or electrostatic operation. A typical electrodynamic actuation means uses f. i. solenoids and an electrostatic actuation means uses piezoelectric elements for instance.

The concatenation module 11 and the valve drive 12 constitute a modular structural unit 21. The concatenation module 11 is in the working example seated at the top on the valve drive 12 and is connected with same by welding and/or by adhesive and more particularly by ultrasonic welding. The structural unit 21 is attached to the side on the valve arrangement 13, for example using screws 22 at a pilot valve unit 95 of the valve arrangement 13. An alternative design of the structural unit 21 could be such that there is also a pilot valve arrangement. The front end face 23 of the concatenation module 11 in the present case lies on the valve arrangement 13. In addition projections of the valve arrangement 13 could fit into recesses in the concatenation module 11 and/or in the valve drive 12. The screws 22 are inserted from the rear end side 25 of the valve drive 12, which together with the rear end side 24 of the concatenation module 11 constitutes an essentially flat surface, through the valve drive 12 and screwed into the valve arrangement 13. It is possible to detach the structural unit 21 with the valve battery 14 mounted, possibly after previously slackening off a tie, not illustrated in the figure. Substitution of defective components is possible.

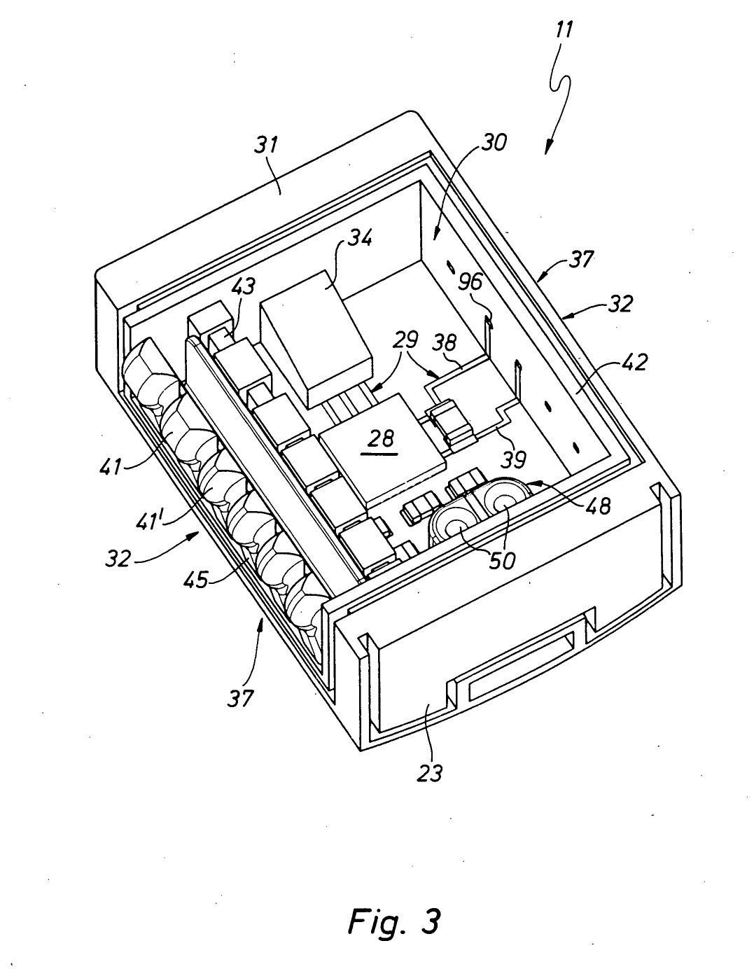

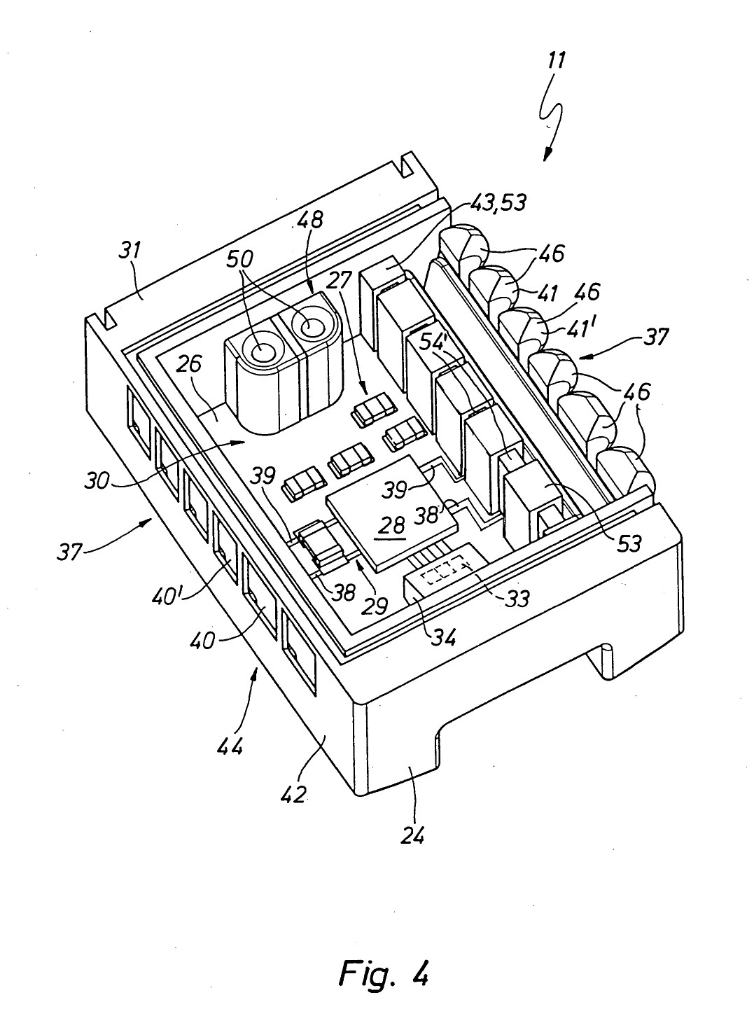

In FIGS. 3 and 4 concatenation module 11 is illustrated as seen looking obliquely upward, its receiving space 26 for electrical components, for example control components 27 being visible. The control components 27 are for example capacitors, resistors and more especially a control semiconductor component 28 are directly arranged on the only partly illustrated printed wiring 29 of the concatenation module 11, whose housing 31 serves as a circuit substrate 30. The control semiconductor component 28, in the following termed merely “chip 28”, controls and monitors the functions of the valve drive 12. Furthermore the control semiconductor component 28, which is for instance an ASIC, serves for communication with adjacent valve subassemblies 10 and/or the local control unit in the terminating module 15. The chip 28 comprises a bus interface for example and furthermore input and output interfaces. In the present case the chip 28 has a power down mode means integrated in it for the valve drive 12. Moreover, it may perform diagnostics on the function of the valve drive 12 and of the valve arrangement 13 and signalize the correct functioning on incorrect functioning of the components 12 and 13. For instance, the chip 28 will send corresponding report telegrams by way of contacting concatenation contacts 37 of the concatenation module 11, to the central control in the terminating module 15.

Furthermore the concatenation module 11 indicates current diagnostic parameters optically. For this purpose the chip 28, in the case of which it is for example a question of an ASIC or a micro-controller, has illuminating means 33, for instance LEDs in different colors, which are also arranged on the printed wiring 29. The illuminating means 33 are, like the other control components 27 for example soldered to the printed wiring 29 or connected in some other way with same electrically. In the present case it is a question of these components being so-called surface mounted device (SMD) components which render possible a particularly compact design. The illuminating means 33 are arranged in a protected manner in the receiving space 26. Light signals produced by them are conducted by a light guide 34, for example of a transparent plastic, to the outer face of the concatenation module 11. The light guide 34 has an oblique outer face and comes to an end essentially in a planar manner at a recess 36, same extending obliquely between the end side 24 and the top side 35 of the concatenation module 11. Accordingly the light signals from the illuminating means 33 are also readily visible from above and from the side in the case of the concatenation module 11 being mounted in the valve battery 14.

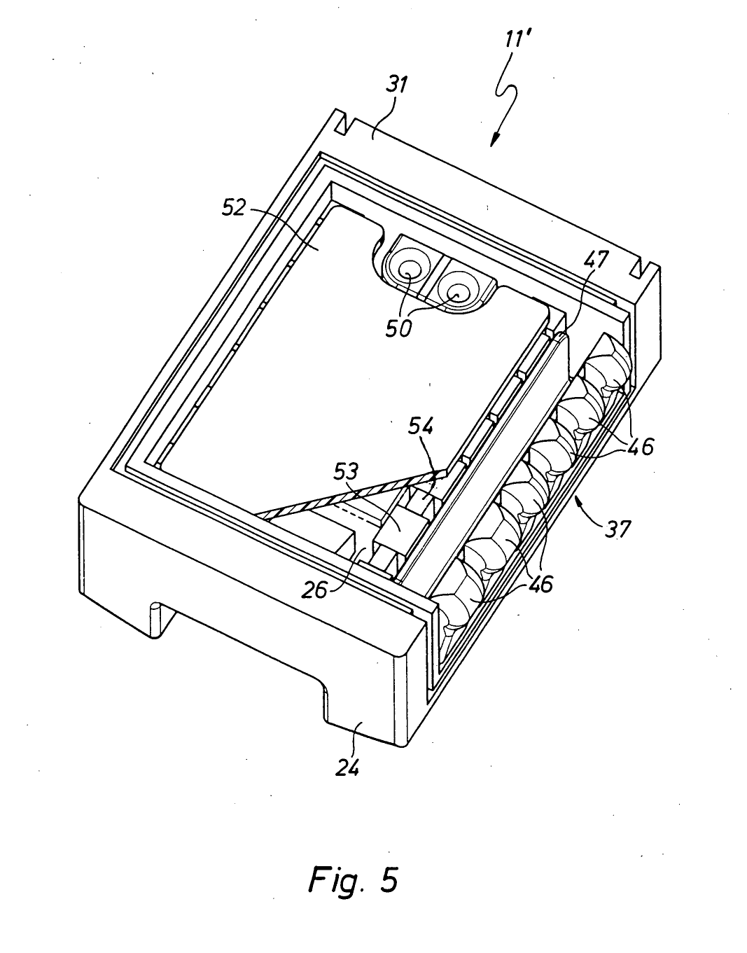

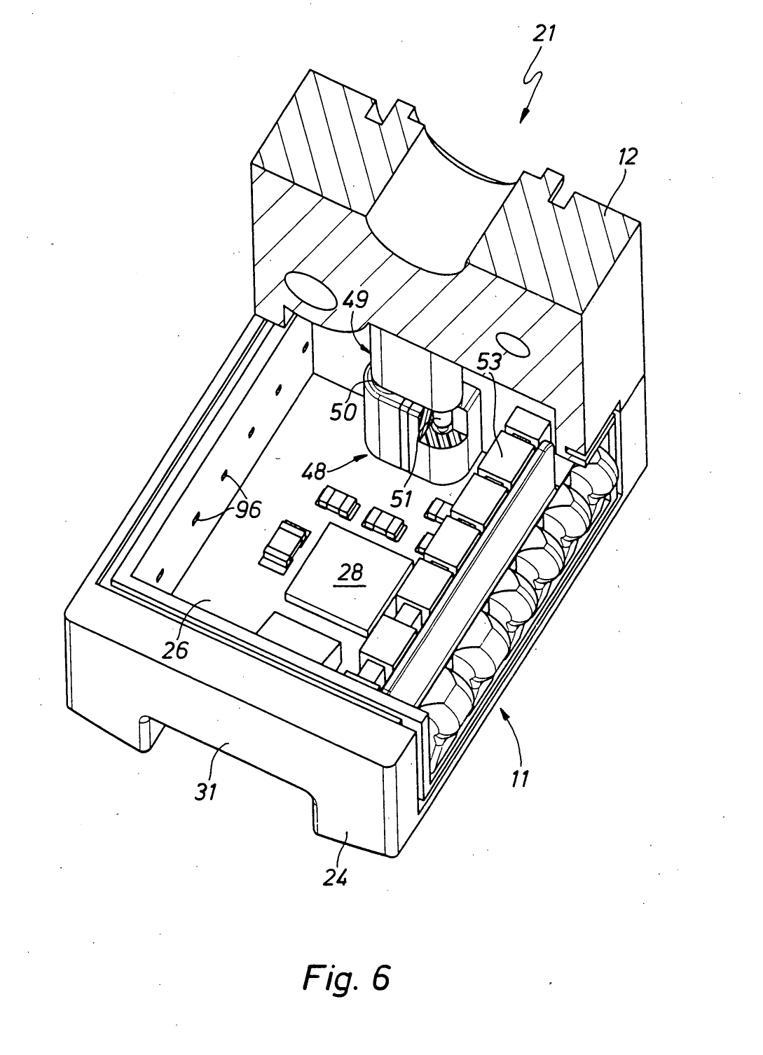

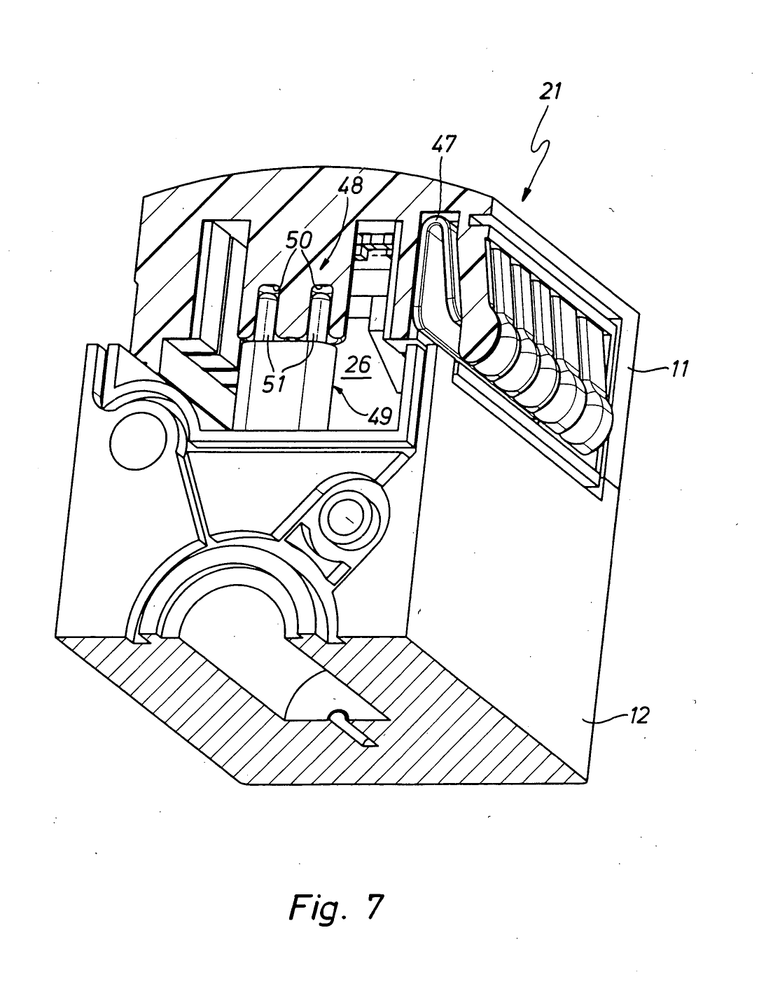

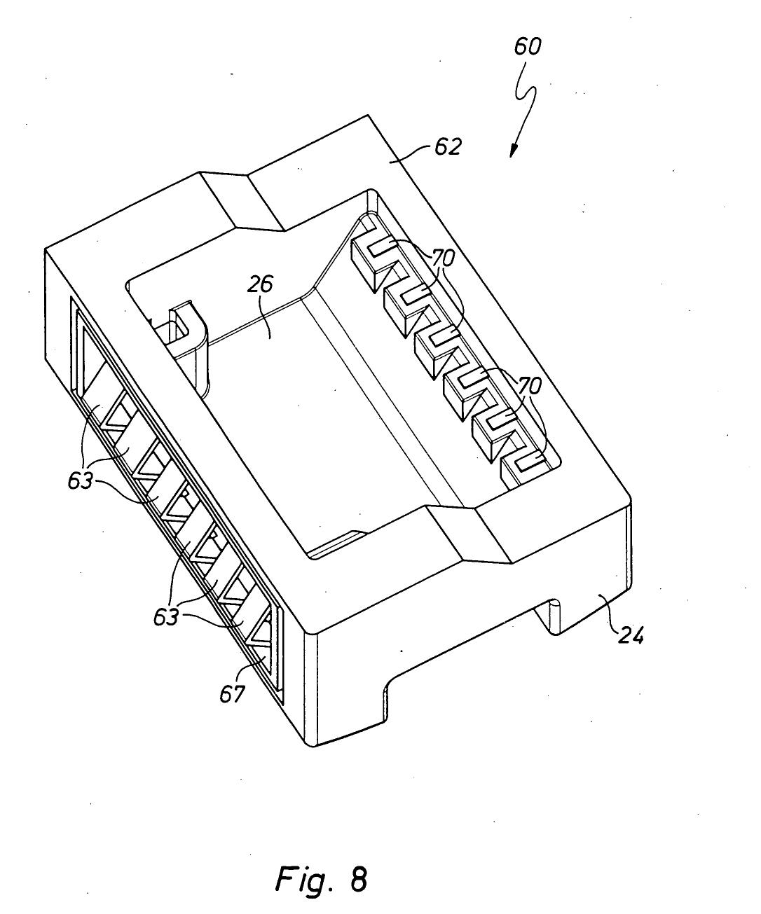

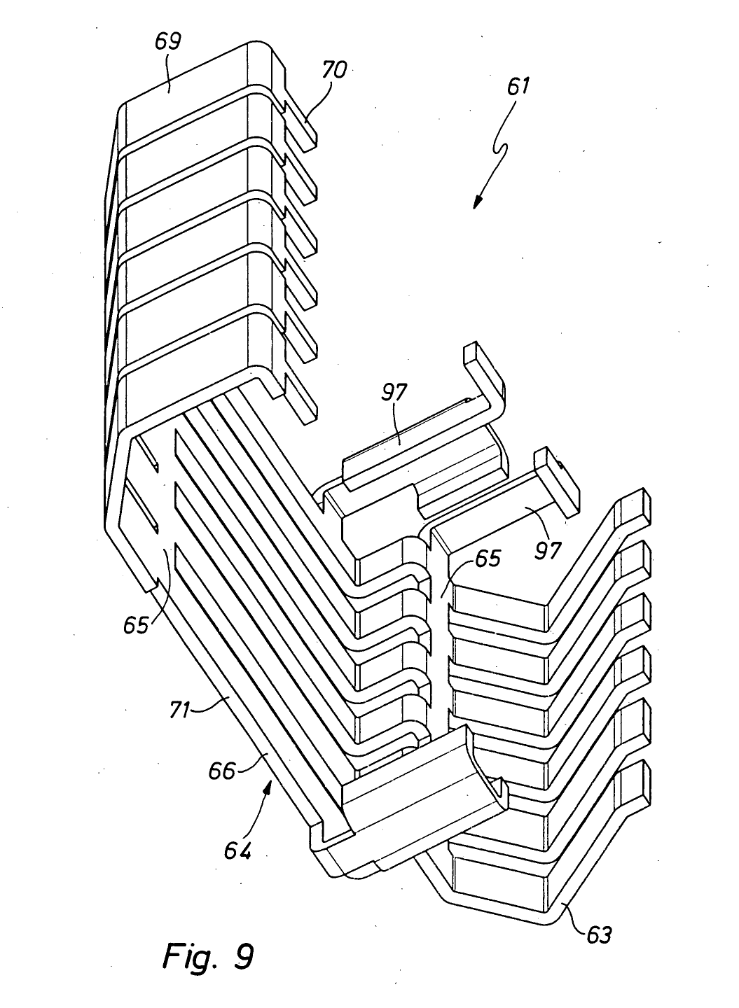

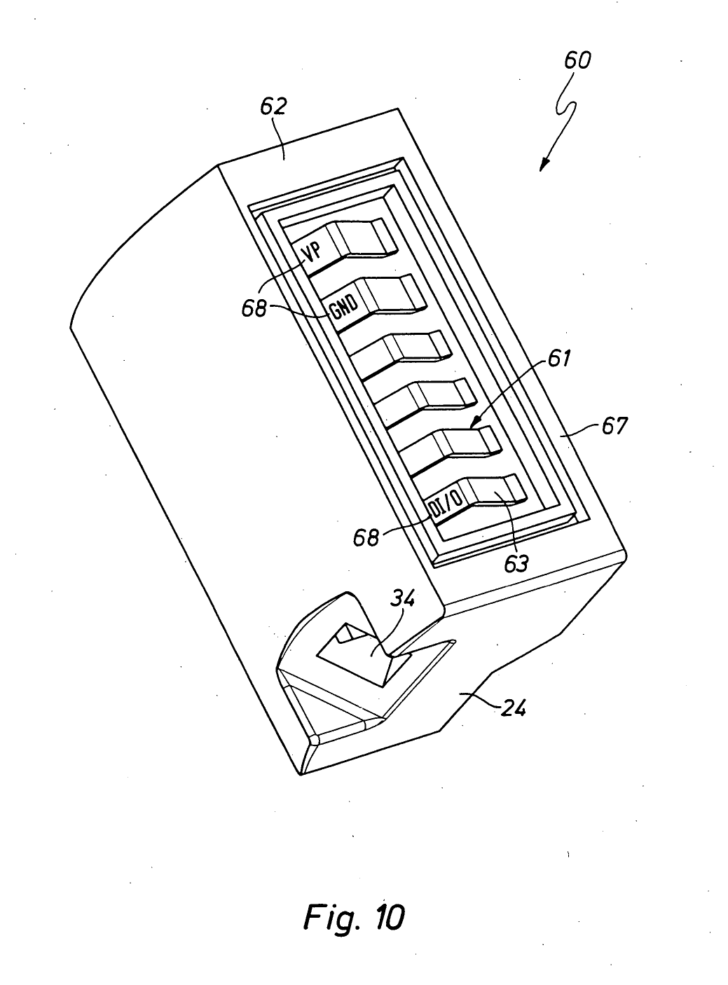

The housing 31 of the concatenation module 11 serves as a three-dimensional circuit substrate 30, in the case of which printed wiring runs on the and/or in the housing, possibly in many layers as a so-called multi-layer structure. Therefore a separate printed circuit board, on which electrical components are arranged, is not absolutely necessary, although a further design in accordance with the invention, to be explained in connection with FIG. 5, additionally uses such a printed circuit board. In the case of the printed wiring a plurality of designs are possible, which may be combined together in any desired manner. The concatenation module 11 illustrated in FIGS. 3 through 8 comprises printed wiring produced by vapor coating and/or by electroplating on the housing 31, whereas the concatenation module 60 (FIGS. 8 through 10) has an integrated metallic stamped and bent part 61, which at least partially constitutes printed wiring of a three-dimensional circuit substrate.

For the manufacture of the housing 31 MID methods are more especially suitable. Different MID methods being suitable. Such method may also be employed in connection with a stamped and bent part, which is explained later.

In the present case the housing 31 is produced by the so-called two shot method (2K method). In this case for example in a first shot a basic housing, a so-called premolding, is molded using a metallizable plastic. Then the spaces between the printed wiring elements are filled with a non-metallizable plastic. In the case of a preferred embodiment of the invention this second plastic is laser-activatable. After this a metal layer is selectively electroplated on the printed wiring regions, for which purpose palladium seeds are provided on the metallizable plastic. As a plastic one with the designation PA66-GF, PC/ABS or LCP (Vectra E820i/Pd) is preferred. Moreover, other metallizable plastics such as polyarylamide (PAA), polyphthalamide (PPA) or polybutylene terephthalate (PBT) are suitable. The two last-named plastics, PPA and PBT, are more particularly advantageous in connection with the following soldering operation of the electrical components, it also being possible in principle to employ other plastics. Laser-activatable plastics are for example PA6/6TMID, PBTMID or PPMID, which are marketed by the company LPKF Laser & Electronics AG, 30827 Garbsen, Germany.

A combination of two component injection molding method (2K method) with following metallization and/or structuring of the surface is particularly preferred, as is as such employed in mono-component injection molding. For instance in the second shot a laser activatable plastic is utilized. It is in this manner that using a laser the layout required in the receiving space 26 is given the necessary structure. Owing to the laser beam sweeping over the surface of the laser-activatable plastic there is a local activation of its surface, by which the desired circuit layout is produced. In the beamed surface region there is a local activation of material. On the one hand metal seeds are split off from special non-conductive active substances or the metal seed casing is cracked open. Simultaneously further filling substances of the plastic material may produce a certain degree of roughness on the irradiated surface regions. Accordingly on the second substrate, which is not inherently metallizable, suitably activated metallization patterns are produced, on which in the course of a following electroplating process metallization may occur. At the split off and partly freed metal seeds there is for example a local metallization with copper following the laser path and owing to the roughness highly satisfactory adhesion for the metal layer produced in the electroplating bath is ensured.

In an alternative subtractive method, as an example, the molding is for instance firstly chemo-electroplated for metallization over the full surface and is coated with an etch resist. The laser removes the etch resist in the region between the printed wiring elements so that the exposed copper may be etched away. Then the remaining etch resist is removed by the laser and then the copper surface is protected, for instance by metallization, against oxidation. Therefore extremely fine printed wiring structure with a distance between them of for example 50 μm may be produced.

Furthermore the printed wiring structure may also be produced by hot stamping. In this case a hot metal stamp is employed to simultaneously stamp out an electrically conductive foil and emboss it on the circuit substrate. Furthermore the desired structure of the printed wiring may be produced by physical vapor deposition (PVD). Here the printed wiring layers are applied by sputtering or vapor deposition in a vacuum, only two process steps, namely activation and metallization being necessary. Extremely homogeneous layers are obtained. Moreover, there is the possibility for later reinforcing such layers by electroplating.

For producing the structure of the printed wiring it is accordingly possible to utilize known subtractive, semi-additive and additive methods. In the subtractive process firstly a metal layer is deposited on the full area up to the desired layer thickness and then the structure is produced. It is possible as well to set the printed wiring structure even on the chemically formed metal layer and as part a semiadditive to reinforce or thicken it until the desired layer thickness is obtained. In the additive process the printed wiring structure is set even before metallization and then metal is built up on this structure selectively.

The advantages of the MID method or, respectively, the use of a stamped and bent part cast or molded in the housing of the concatenation module 60 are that inaccuracies during assembly are prevented, the mechanical load on the electrical control components 27 in the receiving space 26 is low and furthermore owing to a minimized number of electrical transitions the electrical transition resistance may be kept.

In order to reduce the electrical transition resistance there are further measures taken with respect to the concatenation module 11:

On opposite sides of the concatenation module 11 respective concatenation contacts 37 are arranged. When the concatenation module 11 is mounted in the valve battery 14 the concatenation contacts 37 lie flat against the concatenation contacts of an adjacent concatenation module 11 and, respectively, on concatenation contacts of the terminating module 15. The concatenation contacts 37 are preferably looped through pin for pin and constitute the bus 32. This bus may for example be a parallel and/or serial bus, as for example a field bus. Each one pair of concatenation contacts 37 arranged on opposite sides of the concatenation module 11 is provided with a conductor of the bus 32. For reduction of the electrical transition resistance a continuous printed wiring element extends between two respective concatenation contacts 37 arranged on opposite sides of the concatenation module 11. As an example this may be seen in the case of the printed wiring elements 38 and 39. Such printed wiring elements extend from the concatenation contacts 40 and 40′, which are arranged on one side wall 42 of the concatenation module 11, to concatenation contacts 41 and 41′, which are arranged on the opposite side wall 43 of the concatenation module 11. Furthermore the printed wiring 38 and 39 constitutes the contact faces of the concatenation contacts 40, 40′, 41 and 41. Accordingly within the concatenation module 11 there is no impact point between the concatenation contacts 41 and 41′ on the one hand and 40 and 40′ on the other hand.

A further reduction in electrical transition resistance is ensured because the control components 27 are directly arranged on printed wiring (for example printed wiring 38 and 39) linked with concatenation contacts arranged on either side of the concatenation module 11,. For instance a capacitor and the chip 28 are soldered on the printed wiring 38 and 39.

When the valve battery 14 is mounted the concatenation contacts 37 are shut off from the outside (see FIG. 2). On each side wall 42 and 43 the respective concatenation contacts 37 are grouped together as contact regions 44 and 45. The contact regions 44 and 45 can be surrounded by a surrounding plastic or rubber seal. It is also possible to provide only one single U-like seal, which for example protects the contact regions 44 and, respectively, 45 at the top and to the side against effects from the surroundings. Furthermore in the case of the concatenation contacts 37 in the mounted state for adjacent concatenation modules 11 interlocking projections and recesses may be provided.

The working examples include different types of concatenation contacts 37. In the case of the concatenation module 11 the contacts in the contact region 44, for example the concatenation contacts 40 and 40′ are in the form of non-resilient electrical abutment faces. These contact faces are set back in relation to the outline of the housing 31 a small distance so that they are protected.

On the opposite side wall 43 there are metallized plastic members 46, which in the mounted state of the concatenation module 11 make electrical contact with non-resilient electrical engagement face of an adjacent concatenation module 11 or of the terminating module 15.

In principle it would also be possible to design the plastic members 46 to be resilient, and they could be then subject to a resilient force and provide for contact reliability even without an additional spring member. In the working embodiment however a spring arrangement 47 is utilized which is provided with an electrical non-conductive coating, such spring arrangement 47 biasing the plastic members 46 toward an adjacent concatenation module. The spring arrangement 47 is in the present case an integral spring in the form of a stamped and bent part, which bears against the contact plastic members 46 and the side wall 43. The spring arrangement 47 is in the present case a folded metal strip with a V or U cross section. Owing to the non-conductive coating an electrical connection is prevented between the individual plastic members 46. In principle for electrical insulation it would however also be possible for the plastic members 46 not to be provided, on the side facing the spring arrangement 47, with an electrical conductive metal coating.

The non-conductive coating on the spring arrangement 47 will for example consist of a powder coating and/or a plastic foil. The spring arrangement 47 provides the contact force necessary for making reliable contact so that even in the case of any fatigue of the material of the plastic of the members 46 the necessary contact reliability is ensured. The side wall 43 serves as an abutment for the spring arrangement 47. The spring members 46 are borne in the housing 31 in a movable manner and in the present case are made integral with same.

In the case of a comb-like design (not illustrated) of the spring arrangement, in which for example each tooth is associated with one metallized plastic member 46, or if each plastic member 46 is associated with a separate spring member, the contact force would be provided individually for each single plastic member 46, something which would allow for manufacturing inaccuracies as regards the individual plastic members 46 of the contact region 45 and/or the contacts, arranged on the adjacent concatenation module, of a contact region 44. Such inaccuracies or tolerances may for example be due to bad placement of the concatenation module 11 within the battery 14.

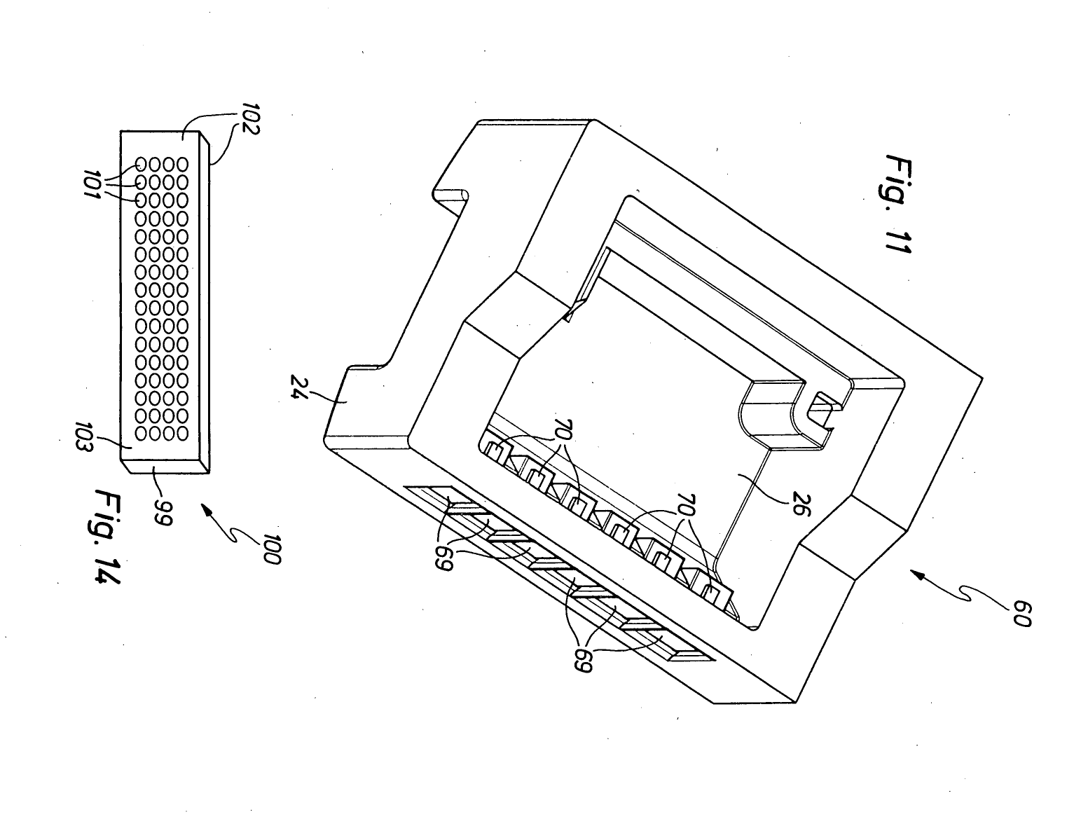

The concatenation contacts 37 may also be designed in the form of metal spring contacts and/or as fuzz button contacts, something which will be explained infra in connection with FIGS. 8 through 11 and, respectively, 12 and 13.

The connection between the concatenation module 11 and the valve drive 12 is produced in a manner representing a sub-combination as a separate development of the invention. During manufacture of the housing 31 and correspondingly during the manufacture of the valve drive 12 manufacturing inaccuracies are inevitable. Such inaccuracies could lead to stresses during assembly of the subassemblies 11 and 12, which in an extreme case could lead to damage of the subassembly 21 comprising the valve drive 12 and the concatenation module 11.

The concatenation module 11 and the valve drive 12 possess mutually cooperating electrical connection means 48 and 49, by way of the concatenation module 11 may control and monitor the valve drive 12. In the present case it is a question of plug connecting means, there being sockets or plug receiving means 50 on the sides of the concatenation module 11 and plug contacts 51 on the valve drive 12. For instance coils (not illustrated) are provided in the valve drive 12, which are surrounded by the housing of the valve drive 12, for example because of manufacture by injection mold and the winding ends are provided with the plug contacts 51. The plug contacts 51 have a smaller diameter than the plug sockets 50. Accordingly they have play in the plug sockets and can therefore introduced into the plug sockets 50 free of stress. The intermediate space between the plug contacts 51 and the plug sockets 50 is filled up with a contact material, for example a conductive adhesive, which is still liquid during assembly before curing and forming a stable and electrically permanent, reliable connection between the connection means 48 and 49. Curing takes place for example after the concatenation module 11 has been bonded to the valve drive 12 and/or welded to it. The plug sockets 50 are for example recesses arranged in the housing 31, which are provided with a metal coating, which for example is applied as part the MID method. This measure as well contributes to a reduction in electrical transition resistance.

Connection leads extend from the outer contact faces of the concatenation contacts 37 and in the present case are constituted by homogeneous printed wiring and extend into the interior, that is to say into the receiving space 26 of the concatenation module 11. For this purpose vias 96 are provided for example.

In the case of the alternative design 11′ of the concatenation module 11 an optional electrical additional component in the form of a printed circuit board 52 is provided. The basic functions of the concatenation module 11′ are essentially performed by the chip 28. If, for a particular application, an additional functionality is required, as for example additional diagnostic functions, the printed circuit board 52 may be mounted in the concatenation module 11′. Thus it is readily possible to adapt the concatenation module 11′ individually to different general conditions, and for example to differently designed valve drives. To take an example in the case of the valve drive 12 designs with different numbers of drive coils would be possible. Furthermore the printed circuit board 52 could comprise a sort of amplification circuit, which is necessary for the control of drive subassemblies having a high power requirement. Furthermore the printed circuit board 52 increases the packing density of the concatenation module 11′.

The printed circuit board 52 is mounted on a substrate structure 53, which is mounted in the receiving space 26. The substrate structure 53 is in the present case constituted by the side wall 43, on whose top side contact faces 54, so-called pads, are arranged for the production of an electrical contact with the printed circuit board 52. The contact faces 54 are in the present case constituted by the printed wiring 38 and 39 or are connected with it electrically so that the electrical transition resistance is comparatively low. In FIG. 5 the printed circuit board 52 is illustrated as being sectioned to disclose underlying components. It will be clear that in principle several printed circuit boards could be arranged in the receiving space 26. Such printed circuit boards could for example be stood vertically in the receiving space.

The concatenation module 11 in accordance with FIG. 4 can also have contact faces 54′, which however are set back in a downward direction relative to the contact faces 54 of the concatenation module 11′. For the production of electrical connections with these contact faces 54′ it is possible to have, for example, projecting contacts on a suitably designed printed circuit board.

In the case of the concatenation module 60 in accordance with FIGS. 8 through 11 on the one hand, as with the concatenation module 11 non-resilient contact faces are provided as concatenation modules 37 while on the other hand however instead of the resilient, metallized plastic members 46 metal spring contacts 63 are provided, which are constituted by a stamped and bent part 61. The stamped and bent part 61 is surrounded by an injected electrically insulating plastic. It constitutes an integral component of the housing 62 of the concatenation module 60. The concatenation module 60 is otherwise the same as the concatenation module 11. In the following identical or similar components have the same reference numeral. Furthermore electrical control components arranged in the receiving space 26 are omitted in order to make the drawing more straightforward.

FIG. 9 shows the stamped and bent part 61 before molding material on it, it however having basically the same outer form as after molding. The stamped and bent part 61 has a sort of grid structure with a longitudinal structure 64 with blades 66 held together by a transverse structure 65. After molding plastic around it the stamped and bent part 61 has the transverse structure 65 removed from it so that the individual blades 66 of the longitudinal structure 64 are insulated electrically from one another. The blades 66 are then held by the housing 62. In principle it would also be possible for the blades, which are already separated, to have plastic material of the housing 62 molded around them.

Each blade 66 has any U-like cross section. On each limb concatenation contacts 37 are arranged. namely spring contacts 63 and contact faces 69. For the spring contacts 63 a side wall 67 of the housing 62 forms an abutment. The spring contacts 63 are biased away from the housing 62 and have a V-like curvature pointing away from it. On the outside of each metal spring contact 63 there is optional lettering 68, for example VP, GND or DI/O, which denotes the supply voltage present at the respective metal spring contact 63 such as ground (GND) or some other bus signal, f. i. DI/O=digital input/output. On the side opposite to the metal spring contacts 63 the blades 66 constitute contact faces 69, which in the mounted state are not resilient and constitute an abutment for spring contacts of a concatenation module arranged adjacent to the concatenation module 60.

Adjacent to the contact faces 69 there are the free ends of the blades 66. They are bent inward and constitute contact faces 70, on which, like those on the contact faces 54 of the concatenation module 11, a printed circuit board or other electrical component can be mounted. From the two outer lateral blades 66 support elements 97 project, on which at the top contact faces 98 are formed. The contact faces 98 are electrically connected with the outer lateral blades 66 and serve, like the contact faces 70, as electrical contact means and in the present case as a substrate structure as well for electrical components, not illustrated, as for example a printed circuit board.

The middle sections 71 of the blades 66 between the metal spring contacts 63 and/or contact faces 69 are at least partly free in the mounted state of the housing 62. On them electrical components like the control components 27 can be placed. This means that the electrical transition resistance is minimized. The middle sections 71 form a sort of printed circuit board.

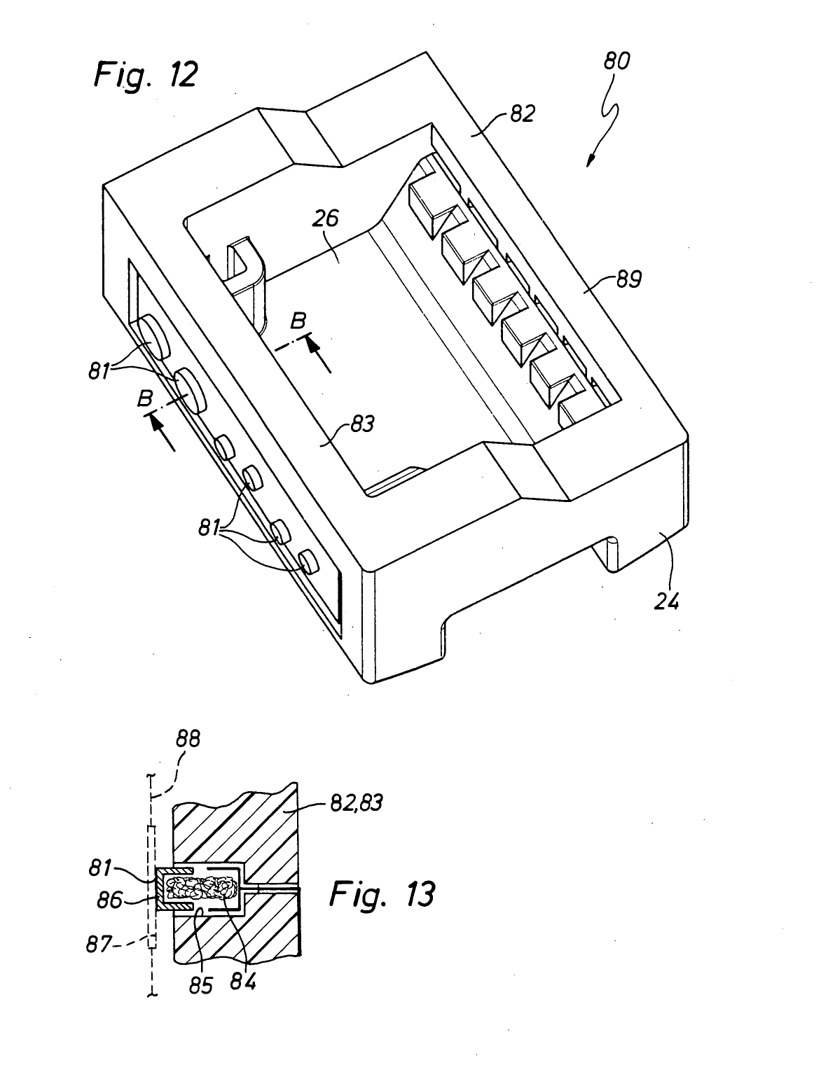

In the case of a concatenation module 80 in accordance with FIGS. 12 and 13 instead of the metallized, resilient plastic members 46 compressible, resilient metal structure contacts, so-called fuzz button contacts, are provided. In other respects the concatenation module 80 is essentially the same as the concatenation module 11, some components not being illustrated in order to make the drawing more straightforward.

The housing 82 is essentially produced using MID technology. The fuzz button contacts 81 are arranged on a side wall 83 of the housing 82. They are essentially constituted by a compressible, resilient metal structure 84, which for example is preformed as a sort of cylinder. The metal structure 84 consists for example of beryllium copper wire with a coating of gold, and is in the form of a ball. The metal structure 84 is seated in a recess 85 in the side wall 83. The recess 85 is lined with an electrically conductive coating, as for example of metal. Preferably the printed wiring elements 29 lead into the recesses 85 so that the electrical transition resistance is reduced. The metallic coating in the recess 85 is for example applied during MID coating.

A rigid cap 86 of electrically conductive material, such as copper sheet, is seated on the metal structure 84, the end side of the cap forming the contact with a contact face 87 of a concatenation module 88 arranged adjacent to a contact face 87 and near the concatenation module 80. Accordingly the metal structure 84 is compressed, that is to say it moves further into the recess 85, the resilient character of the metal structure 84 reliably producing the electrical connection with the contact face 87.

On the side wall 89 opposite to the side wall 83 non-resilient, stationary contact faces 87 like the contact faces 40 and, respectively, 69 are arranged. These contact faces are also somewhat set back from the side wall 89.

It will be clear that fuzz button contacts without a rigid cap 86 are in principle also possible

FIG. 14 shows, partially diagrammatically, a further design of a connection between concatenation contacts, more particularly in the form of non-resilient contact faces. In an electrical insulator 99, of for example silicon, of a connecting element 100 conductors 101 are arranged, for example in the form of fine metal wires. In the figure the conductors are illustrated with a disproportionally large diameter for reasons of clarity. The conductors 101 extend through the insulator 99 and run between the respective end sides 102 of the connecting element 100 and open at the end sides 102. The conductors 101 are embedded in the insulator 99 and are electrically insulated from each other by it.

The conductors 101 in the mounted state, lie for example on non-resilient contact faces 69 or 89 of adjacent concatenation modules 60 or 88 (if same only had non-resilient contact faces 69 or, respectively, 87 instead of the metal spring contacts 63 or, respectively, the fuzz button contacts) and connect the adjacent, opposite contact faces 69 and 87 of adjacent concatenation modules 60 and 88.

During assembly of the concatenation modules 60 and 88 the connecting element 100 assumes a position between the concatenation modules 60 and 88 and is compressed a predetermined amount so that it is seated firmly between the concatenation modules 60 and 88 and the conductors 101 are in reliable electrical contact with the contact faces 69 and 87. By having sufficiently large lateral distances between the contact faces 69 and 87 of a concatenation module 60 and 88 an electrical short circuit between these contact faces 69 and 87 by the connecting element 100 is prevented. An edge region arranged like a frame around the conductors 101 protects the contact faces 89 from environmental effects. In order to receive the connecting element 100 a well may be provided in the contact faces 87.

What is claimed is:

1. A concatenation module adapted to be concatenated with further concatenation modules as a battery, comprising a housing and lateral concatenation contacts on the housing for making electrical contact with at least one further concatenation module, wherein the housing is in the form of a three-dimensional circuit substrate and it comprises at least one electronic component, arranged on the circuit substrate, for at least one of a control function, a monitoring function, and a communication function.

2. The concatenation module as set forth in claim 1, wherein the concatenation contacts make flatwise engagement with one another in the battery-like assembled state of the concatenation modules.

3. The concatenation module as set forth in claim 1, wherein the concatenation contacts are at least one of formed by the housing and constitute an integral component of the housing.

4. The concatenation module as set forth in claim 1, comprising printed wiring applied by at least one of vapor deposition, electroplating, hot stamping, and formed by at least one integrated metallic stamped and bent part.

5. The concatenation module as set forth in claim 1, wherein the concatenation contacts are, in the battery-like mounted state, shut off from the outside.

6. The concatenation module as set forth in claim 1, wherein the concatenation contacts are arranged on opposite sides of the concatenation module and are connected with each other by continuous printed wiring.

7. The concatenation module as set forth in claim 6, wherein the continuous printed wiring constitutes contact faces of the concatenation contacts.

8. The concatenation module as set forth in claim 1, wherein it is able to be connected with a module unit to be at least one of controlled and monitored, the concatenation module and the module unit together forming a battery module, which is able to be coupled with further battery modules to form a module battery.

9. The concatenation module as set forth in claim 8, wherein the at least one electrical component for at least one of controlling the module unit, monitoring the module unit, and communication of the module unit of the concatenation module is provided with further battery modules or a control of the battery.

10. The concatenation module as set forth in claim 9, wherein the at least one electrical component is arranged on at least one continuous printed wiring element which connects two concatenation contacts arranged on opposite sides of the concatenation module and said at least one electrical component is an electrically printed wiring element.

11. The concatenation module as set forth in claim 9, comprising a receiving space, which is closed in the assembled state, for the at least one electrical component.

12. The concatenation module as set forth in claim 8, comprising connecting means, and more particularly plug connecting means, for electrical connection with the module unit.

13. The concatenation module as set forth in claim 12, wherein the connecting means of the concatenation module are connected with cooperating connecting means of the module unit in the mounted state by means of a conductive adhesive, such adhesive filling an intermediate space otherwise present between the respective connecting means.

14. The concatenation module as set forth in claim 12, which is at least one of welded and bonded to the module unit.

15. The concatenation module as set forth in claim 1, wherein concatenation contacts arranged on one respective side of the concatenation module are grouped together to form a contact region provided with a sealing means sealing it off from the outside.

16. The concatenation module as set forth in claim 1, wherein the concatenation contacts are constituted by at least one of a metallized plastic member, by metal spring contacts, by fuzz button contacts, and by non-resilient electrical engagement faces.

17. The concatenation module as set forth in claim 1, comprising, for electrical connection of the concatenation contacts of adjacent concatenation modules with one another, mutually electrically insulated conductors arranged in an elastic insulator, such elastic insulator coming to lie in the mounted state between the adjacent concatenation module and the electrical conductors connecting the concatenation contacts of the processing modules.

18. The concatenation module as set forth in claim 1, wherein the concatenation contacts comprise metallized plastic members, which are biased by a metallized spring arrangement provided with an electrically non-conductive coating and having at least one spring and/or a metallic spring comb.

19. The concatenation module as set forth in claim 1, wherein the concatenation contacts are essentially constituted by a substrate structure produced in a two component injection molding process and wherein in the interior of the concatenation module a printed wiring structure is formed on laser activated material.

20. The concatenation module as set forth in claim 1, comprising illuminating means for indicating at least one function of the concatenation module.

21. The concatenation module as set forth in claim 1, adapted to be coupled permanently or connected with a fluid power valve arrangement and forming a valve subassembly which is able to be coupled with one or more further such valve subassemblies to form a valve battery and said concatenation module comprises an electrical valve drive for the actuation of at least one of the fluid power valve arrangement and connecting means for an electrical connection and operation of an electrical valve drive for actuation of the fluid power valve arrangement.

22. A module unit comprising a valve subassembly, the value subassembly comprising:
at least one concatenation module, the concatenation module adapted to be concatenated with further concatenation modules as a battery, the concatenation module comprising a housing and lateral concatenation contacts on the housing for making electrical contact with at least one further concatenation module, wherein the housing is in the form of a three-dimensional circuit substrate and contains at least one electronic component arranged on the circuit substrate, for at least one of a control function, a monitoring function, and a communication function.
